(19) United States
(12) Patent Application Publication
(10) Pub. No.: US 2025/0112202 A1
(43) Pub. Date: Apr. 3, 2025

(54) THERMAL INTERFACE MATERIAL ON A SURFACE OF A DIE IN A CAVITY

(71) Applicant: Intel Corporation, Santa Clara, CA (US)

(72) Inventors: Abdallah BACHA, Munich (DE); Cindy MUIR, Tempe, AZ (US); Mohan Prashanth JAVARE GOWDA, Ottobrunn (DE); Stephan STOECKL, Schwandorf (DE); Thomas WAGNER, Regelsbach (DE); Wolfgang MOLZER, Ottobrunn (DE)

(21) Appl. No.: 18/374,948

(22) Filed: Sep. 29, 2023

(51) Int. Cl. H01L 25/065; H01L 23/00; H01L 23/367; H01L 23/538; H01L 25/10; H10B 80/00

(52) U.S. Cl. CPC H01L 25/0652; H01L 23/367; H01L 23/5386; H01L 24/29; H01L 24/32; H01L 25/105; H10B 80/00; H01L 2224/29144; H01L 2224/29147; H01L 2224/29193; H01L 2224/32225

(57) ABSTRACT

Embodiments herein relate to systems, apparatuses, or processes for packages that include substrates that include one or more die in a cavity within the substrate, where sides and a bottom of the cavity are lined with a heat spreader, or TIM, material that is thermally coupled to a side of the substrate using thermally conductive vias. In embodiments, thermally conductive vias may be thermally coupled with the heat spreader at the side of the substrate. Other embodiments may be described and/or claimed.

Embodiments of the present disclosure generally relate to package assemblies, and in particular package assemblies that include dies within cavities in a substrate.

### BACKGROUND

Continued reduction in end product size of mobile electronic devices such as smart phones and ultrabooks is a driving force for the development of reduced size system in package components to maintain enhanced performance.

### BRIEF DESCRIPTION OF THE DRAWINGS

FIG. 1 illustrates a cross-section side view of a legacy package that includes a substrate with a high-bandwidth memory (HBM) in a cavity within the substrate.

FIG. 2 illustrates a cross-section side view of a package that includes a layer, which may be a thermal interface material (TIM), surrounding an HBM in the cavity within the substrate, with vias thermally coupling the TIM to a heat spreader on the bottom of the package, in accordance with various embodiments.

FIG. 3 illustrates a perspective view of various patterns of a TIM surrounding a HBM, in accordance with various embodiments.

FIG. 4 illustrates a cross-section side view of a package that includes TIM surrounding an HBM, with a first heat spreader at the top of the package and a second heat spreader at the bottom of the package, with vias thermally coupling the first heat spreader at the second heat spreader, in accordance with various embodiments.

FIG. 5 illustrates a cross-section side view of a package similar to the package of FIG. 4, with solder balls coupled to the second heat spreader, in accordance with various embodiments.

FIG. 6 illustrates a cross-section side view of a package similar to the package of FIG. 4, where the package is implemented with a flex interposer, in accordance with various embodiments.

FIG. 7 illustrates a top-down view of a package that shows various configurations of die complexes above multiple HBM in cavities within a substrate, in accordance with various embodiments.

FIGS. 8A-8E illustrate stages in a manufacturing process for creating a package with a TIM on the surface of a die in a cavity within a substrate, in accordance with various embodiments.

FIG. 9 illustrates an example of a process for creating a package with a TIM on the surface of a die in a cavity within a substrate, in accordance with various embodiments.

FIG. 10 schematically illustrates a computing device, in accordance with embodiments.

### DETAILED DESCRIPTION

Embodiments of the present disclosure may generally relate to systems, apparatus, techniques, and/or processes directed to packages that include substrates with one or more cavities within the substrate, where the cavities include one or more dies, and where the cavities are lined with a layer that may include a heat spreader, or TIM, material. In embodiments, the TIM material within the cavities may be thermally coupled to a heat spreader at a side of the substrate. In embodiments, this thermal coupling may be accomplished through one or more vias that are filled with a thermally conductive material.

In embodiments, a HBM may be placed in a cavity and thermally coupled with the TIM material. In embodiments, an interposer may be on top of the substrate and electrically coupled with the HBM. In embodiments, there may be one or more dies, for example but not limited to a processor die, an I/O die, a graphics processor die, a network die, or some other die that may be electrically coupled with the HBM through the interposer. These dies may be referred to as computer/network dies.

In embodiments, heat generated during operation of the HBM may be routed through the TIM surrounding the HBM and downward through the substrate to the bottom of the substrate through one or more vias and to a heat spreader at the bottom of the substrate. In other embodiments, there may be a heat spreader on top of the one or more dies that are on the interposer, and there may be one or more vias that extend from the heat spreader on top of the one or more dies, extend through the interposer and the substrate, and thermally couple with the heat spreader on the bottom of the substrate.

In legacy implementations, computer/network dies may be above HBM dies that are located in cavities within the substrate in order to reduce the distance of electrical connections between the computer/network dies and the HBM dies. However, in these legacy implementations, there is a challenge with heat, or thermal energy, generated during operation of the HBM that may require a clock rate to be lowered in order for the package to not overheat. However, there is an advantage to more effectively route heat from the HBM dies during operation in order to support a higher clock rate and therefore higher operational performance for the package.

In embodiments, the TIM may be placed on the sides and/or at the bottom of the cavity prior to the insertion of the HBM dies into the cavities. In other embodiments, the TIM may be placed on one or more surfaces of the HBM dies either prior to or after insertion into the cavities. In embodiments, the TIM may include, for example, copper, gold, and/or graphene. In embodiments, overall package thermal conductivity is increased, which facilitates faster heat removal from the HBM, or other die sources within a cavity, and as a result keeps the HBM or die temperatures lower. In embodiments, the techniques described herein may enable packages to have a higher Thermal Dissipation Power (TDP) before the package reaches a maximum allowed junction temperature.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

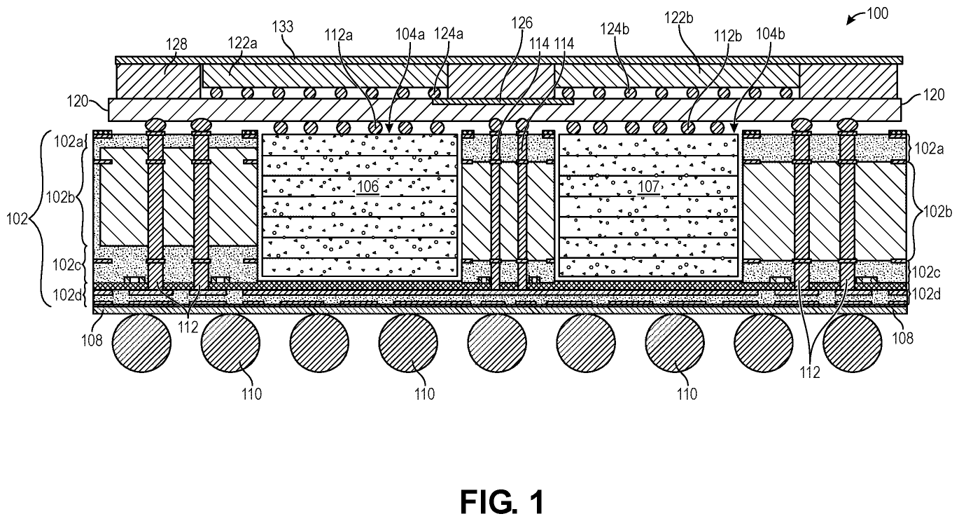

FIG. 1 illustrates a cross-section side view of a legacy package that includes a substrate with a high-bandwidth memory (HBM) in a cavity within the substrate. Legacy package 100 may include a substrate 102 that may include cavities 104a, 104b. In legacy implementations, the cavities may extend from a top of the substrate 102 toward the bottom of the substrate 102. The cavities 104a, 104b may be within a top routing layer 102a, a dielectric layer 102b, which may be referred to as a core, and bottom routing layer 102c. In legacy implementations, the cavities 104a, 104b may be above a bottom redistribution layer 102d, which may be a multi-layer redistribution layer. There may be a heat spreader 108 at the bottom of the substrate 102, and the heat spreader 108 may be physically coupled with one or more solder balls 110, which may be used to transfer heat. In implementations, other solder balls 110 may be used to electrically couple with power vias 112, or may be used to electrically couple with signal vias 114.

In legacy implementations, the HBM 106, 107 may be within, respectively, the cavities 104a, 104b. The HBM 106, 107 may be adjacent to and/or physically coupled with portions of the substrate 102 that include the top routing layer 102a, the dielectric layer 102b, the bottom routing layer 102c, and the bottom redistribution layer 102d.

In legacy implementations, an interposer 120 may be on top of the substrate 102, and may electrically couple with the HBM 106, 107 using solder ball arrays 112a, 112b, respectively. In legacy implementations, the interposer 120 may electrically couple with the power vias 112 and/or the signal vias 114. One or more compute/network dies 122a, 122b may be physically and electrically coupled to the interposer 120 using one or more solder ball arrays 124a, 124b. In some implementations, the compute/network dies 122a, 122b may be coupled with a bridge 126 that may provide high-speed communication between the compute/network dies.

In implementations, there may be a filler 128, that may include a mold compound and may be referred to as a moldcap, that at least partially surrounds the compute/network dies 122a, 122b. In some implementations, a heat spreader 133 may be on top of the compute/network dies 122a, 122b to draw heat during package operation.

In legacy implementations, additional cooling may have been attempted by increasing the thickness and/or numbers of metal layers within the top routing layer 102a, and bottom routing layer 102c, or by increasing the metal contact within the dielectric layer 102b. In legacy implementations, the dielectric layer 102b may have been chosen to use higher thermal conductive material, or copper and/or silicon dummy parts (not shown) may be inserted within the substrate 102 to draw heat.

In other implementations, the bump counts for the solder balls 110 may have been increased in an attempt to draw more heat from the heat spreader 108. In other implementations, active cooling structures (not shown), such as liquid cooling, may be incorporated within the substrate 102. Disadvantages of these legacy implementations are that increasing the ball or bump count artificially increases the area of the legacy package 100 resulting in higher costs. Similarly, active cooling structures require more surface area resulting in higher legacy package 100 size, and also increase costs.

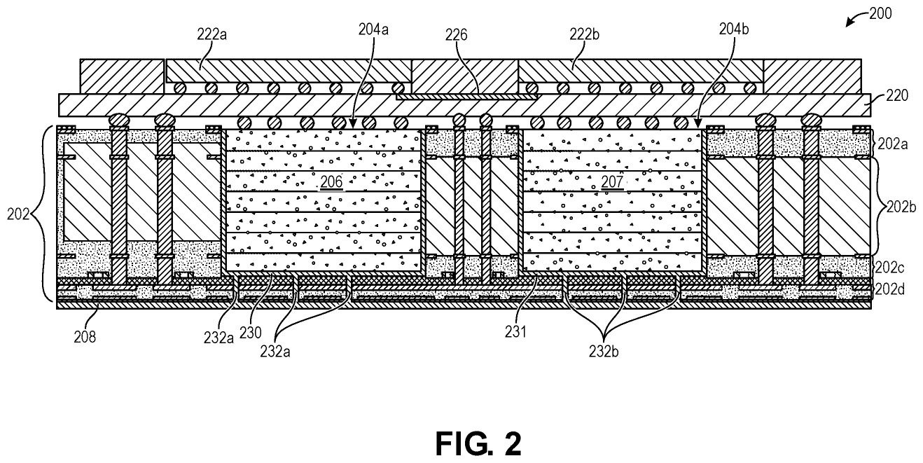

FIG. 2 illustrates a cross-section side view of a package that includes a layer, which may be a TIM, surrounding an HBM in the cavity within the substrate with vias thermally coupling the TIM to a heat spreader on the bottom of the package, in accordance with various embodiments. Package 200, which may be similar to legacy package 100 of FIG. 1, includes a substrate 202 and cavities 204a, 204b, into which HBM 206, 207 are inserted. Substrate 202, cavities 204a, 204b, and HBM 206, 207 may be similar to substrate 102, cavities 104a, 104b, and HBM 106, 107 of FIG. 1. Substrate 202 may include redistribution layer 202d, bottom routing layer 202c, dielectric layer 202b, and top routing layer 202a, which may be similar to redistribution layer 102d, bottom routing layer 102c, dielectric layer 102b, and top routing layer 102a of FIG. 1.

In embodiments, the side walls and/or bottom of the cavities 204a, 204b may include TIM 230, 231. In embodiments, the TIM 230, 231 may be formed out of a metal, which may include but not limited to sputtered or plated copper. In embodiments, the TIM 230, 231 may include other materials such as gold or graphene. In embodiments herein, references to a TIM, such as TIM 230, 231, may also refer generally to a layer of material. In embodiments, the HBM 206, 207 are thermally coupled, respectively, with the TIM 230, 231. In embodiments, the heat spreader 208 may include the TIM 230, 231 materials, or may also include aluminum, and/or silicon.

In embodiments, one or more vias 232a and one or more vias 232b may be formed within the substrate 202 and thermally couple the HBM 206, 207 with the heat spreader 208, which may be similar to heat spreader 108 of FIG. 1. In embodiments, the one or more vias 232a, 232b may be filled with a thermally conductive material, which may be similar to the material in the TIM 230, 231. In embodiments, the one or more vias 232a, 232b may take a shape other than a via, such as blocks of thermally conductive material or planes of thermally conductive material.

In embodiments, a gap between the HBM 206 and a side of the cavity 204a may be filled with a TIM 230, which may fill the gap for conductive contact. In some embodiments there may be a combination of a metal layer (not shown) that is in thermal contact with the HBM 206 and the TIM 230 may be between the metal layer and the substrate 202. In embodiments, there may be an interposer 220 and there may be computer/network dies 222a, 222b on the interposer 220. In embodiments, there may be a bridge 226 that provides high speed networking connection between the computer/network dies 222a, 222b. In embodiments, the interposer 220, computer/network dies 222a, 222b, and bridge 226 may be similar to interposer 120, computer/network dies 122a, 122b, and bridge 126 of FIG. 1.

In some embodiments, in addition to the thermal improvement, the TIM 230 may be electrically coupled with a ground in order to provide electromagnetic shielding for the HBM 206 from the surrounding vias and/or layers within the substrate 202.

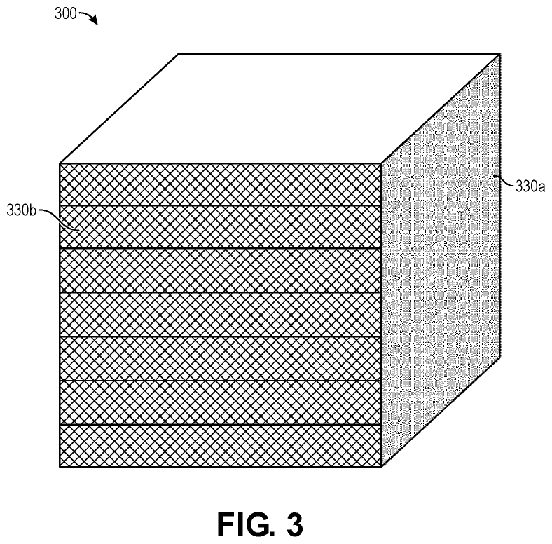

FIG. 3 illustrates a perspective view of various patterns of a TIM surrounding a HBM, in accordance with various embodiments. HBM 300, which may be similar to HBM 206, 207 of FIG. 2, shows a perspective view with different patterns of TIMs 330a, 330b, which may be similar to TIM 230, 231 of FIG. 2, on the sides of the HBM 300. In embodiments, TIM 330a on a side of the HBM 300 may be a solid layer, where the TIM 330b on a different side may have a lattice pattern, where parts of the side of the HBM 300 is not covered. In some embodiments, a bottom (not shown) of the HBM 300 may include a thicker layer of TIM then may be on a side TIM 330a.

In embodiments, the TIM may fully surround all five sides of the HBM 300. In embodiments, the TIM may be metal casings, which may be directly connected to the heat spreader, such as heat spreader 208 of FIG. 2, to facilitate better thermal performance. In embodiments, depending upon cooling requirements, the TIM may be only on the sidewalls are only on the bottom of the cavity, such as cavity 204a of FIG. 2, being covered. In embodiments, the TIM on different sides of the HBM 300 may have different materials and/or different thicknesses, depending upon the gap sizes between the HBM 300 and the cavity. In embodiments, different TIM materials may be used depending on thermal resistance requirements.

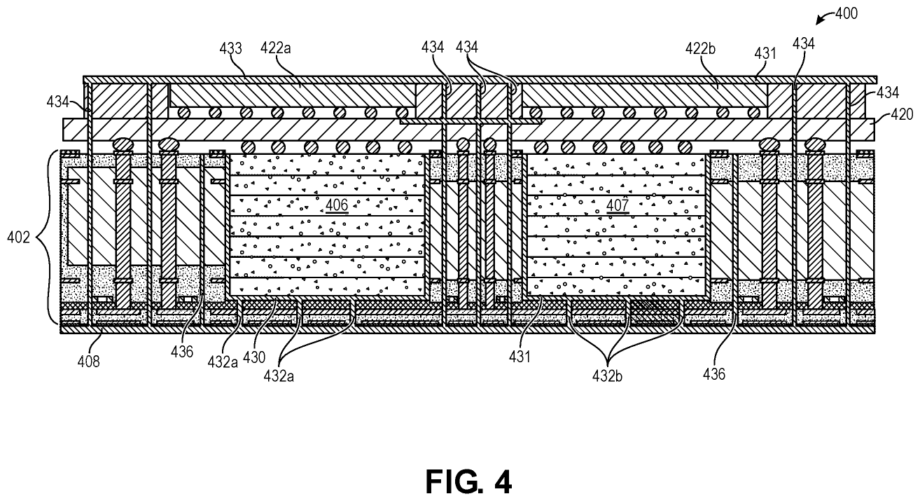

FIG. 4 illustrates a cross-section side view of a package that includes TIM surrounding an HBM, with a first heat spreader at the top of the package and a second heat spreader at the bottom of the package, with vias thermally coupling the first heat spreader at the second heat spreader, in accordance with various embodiments. Package 400, which may be similar to package 200 of FIG. 2 includes a substrate 402, HBM 406, 407, and TIM 430, 431 surrounding the side and bottom of the HBM. The TIM 430, 431 are thermally coupled with a heat spreader 408 at a bottom of the substrate 402 using a plurality of vias 432a, 432b.

An interposer 420, may be electrically coupled with the HBM 406, 407, and have computer/network dies 422a, 422b electrically coupled with the interposer 420. In embodiments, the substrate 402, HBM 406, 407, TIM 430, 431, heat spreader 408, and one or more vias 432a, 432b may be similar to substrate 202, HBM 206, 207, TIM 230, 231, heat spreader 208, and plurality of vias 232a, 232b of FIG. 2. Computer/network dies 422a, 422b may be similar to computer/network dies 122a, 122b of FIG. 1.

Unlike the embodiment of package 200 shown in FIG. 2, package 400 includes a top heat spreader 433 on top of and thermally coupled with the computer/network dies 422a, 422b. In embodiments, one or more vias 434 may include thermally conductive material to thermally couple the top heat spreader 433 with the bottom heat spreader 408. In embodiments, one or more vias 436 may include thermally conductive material and extend into the substrate 402. The one or more vias 436 may then thermally couple with the bottom heat spreader 408.

In embodiments, the one or more vias 434, 436 may be used to route heat from multiple places within the package 400 to the bottom heat spreader 408.

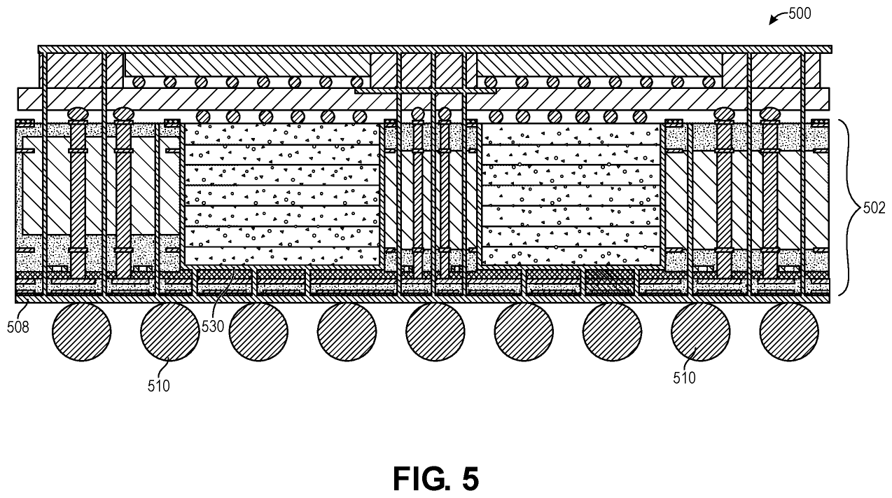

FIG. 5 illustrates a cross-section side view of a package similar to the package of FIG. 4, with solder balls coupled to the second heat spreader, in accordance with various embodiments. Package 500 may be similar to package 400 of FIG. 4, where solder balls 510, which may be similar to solder balls 110 of FIG. 1, may be thermally coupled with the TIM 530 through a physical and/or thermal coupling with the heat spreader 508, which may be similar to heat spreader 408 of FIG. 4. In embodiments, the solder balls 510 may be referred to as package balls, which may be later connected to a printed circuit board (PCB).

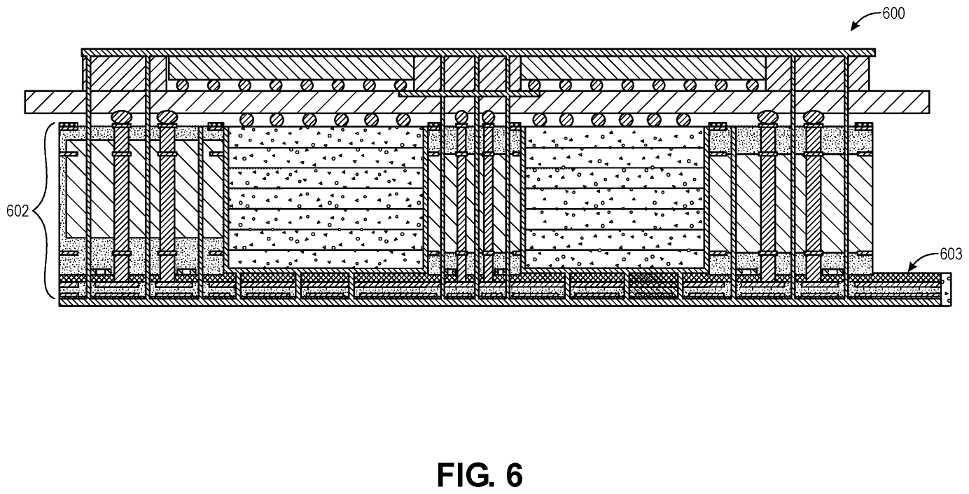

FIG. 6 illustrates a cross-section side view of the package similar to the package of FIG. 4, where the package is implemented with a flex interposer, in accordance with various embodiments. Package 600 may be similar to package 500 of FIG. 5, except that the substrate 602, which may be similar to substrate 402 of FIG. 4, may include a flex substrate with a side connector 603 that may be used to physically and/or electrically couple with other components.

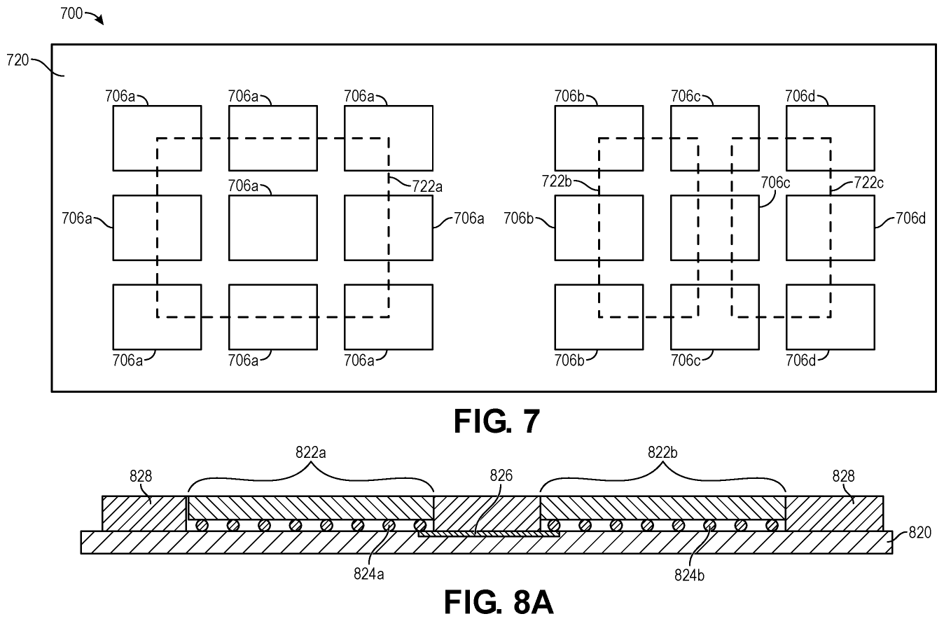

FIG. 7 illustrates a top-down view of a package that shows various configurations of die complexes above multiple HBM in cavities within a substrate, in accordance with various embodiments. Package 700, which may be similar to package 500 of FIG. 5, shows a top-down, partial, semi-transparent view of interposer 720, which may be similar to interposer 420 of FIG. 4. In embodiments, computer/network dies 722a, 722b, 722c may be on the interposer 720. In embodiments, each of a first group of HBM 706a, which may be similar to 406 of FIG. 4, may be below the interposer 720 and electrically coupled with computer/network dies 722a.

In embodiments, a second group of HBM 706b and a third group of HBM 706c may be below and electrically coupled with computer/network dies 722b. In embodiments, the third group of HBM 706c and a fourth group of HBM 706d may be below and electrically coupled with computer/network dies 722c. Note that the bridge, such as bridge 226 of FIG. 2, and the top heat spreader such as top heat spreader 433 of FIG. 4, is not shown.

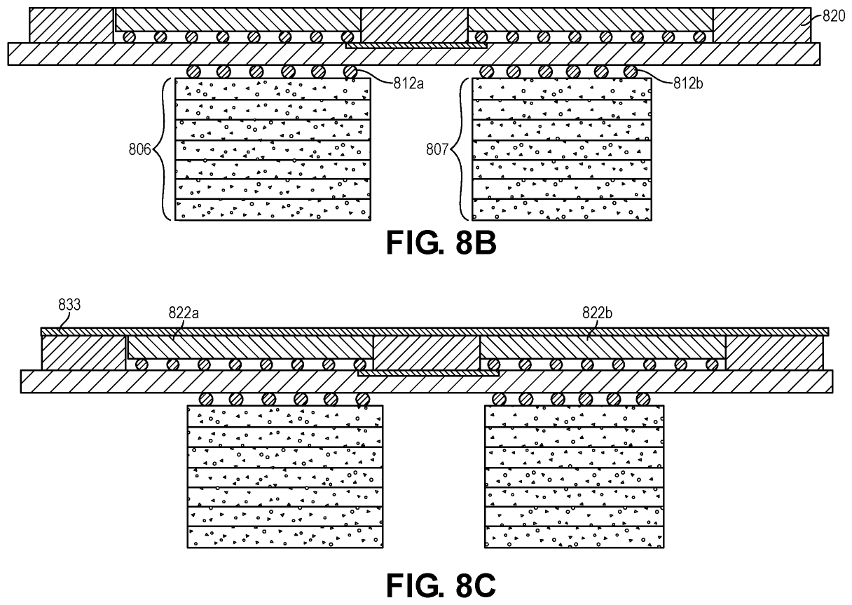

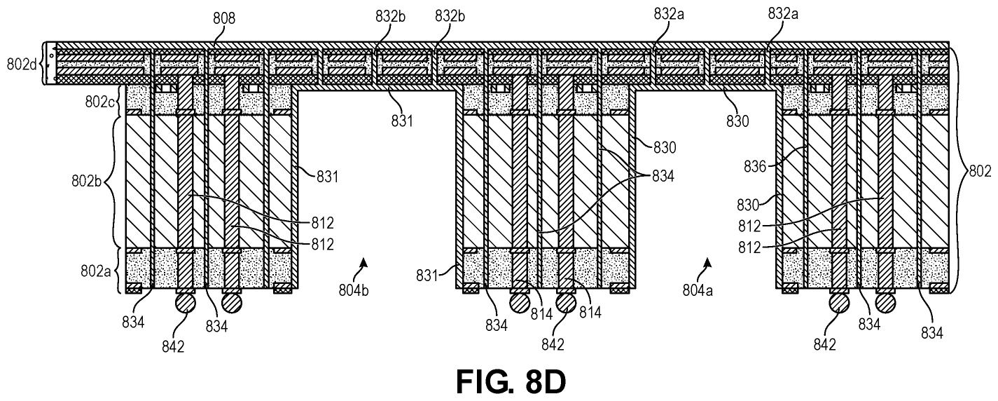

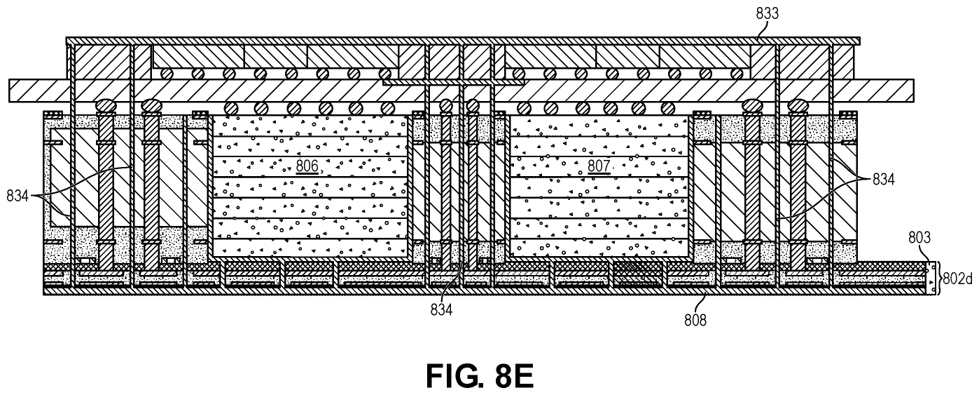

FIGS. 8A-8E illustrate stages in a manufacturing process for creating a package with a TIM on the surface of a die in a cavity within a substrate, in accordance with various embodiments. FIG. 8A illustrates a cross-section side view of a stage in the manufacturing process where an interposer 820, which may be similar to interposer 120 of FIG. 1, is provided. In embodiments, a bridge 826 may be formed on top of or embedded into the interposer 820. In embodiments, solder balls 824a, 824b may be placed on one or more electrical connections (not shown) on the interposer 820, and a first set of compute/network dies 822a and a second set of compute/network dies 822b may be placed, respectively, on the solder balls 824a, 824b.

A filler 828 may be placed on the interposer 820 that at least partially surrounds the computer/network dies 822a, 822b. Subsequent to the placement of the filler 828, the filler 828 and the dies 822a, 822b may be subject to a planarization process. In embodiments, the bridge 826, solder balls 824a, 824b, and compute/network dies 822a, 822b may be similar to bridge 126, solder balls 124a, 124b, and compute/network dies 122a, 122b of FIG. 1. In embodiments, the bridge 826 provides high speed data access between the computer/network dies 822a, 822b.

FIG. 8B illustrates a cross-section side view of a stage in the manufacturing process where solder balls 812a, 812b are applied to a side of the interposer 820. In embodiments, HBM 806 may be electrically and/or physically coupled with solder balls 812a and HBM 807 may be electrically and/or physically coupled with solder balls 812b. In embodiments, the HBMs 806, 807 may be placed beneath or proximate to the computer/network dies 822a, 822b to facilitate a high-speed electrical signal between the HBMs 806, 807 and the computer/network dies 822a, 822b.

FIG. 8C illustrates a cross-section side view of a stage in the manufacturing process where a heat spreader 833 is placed on top of the computer/network dies 822a, 822b. Heat spreader 833 may be similar to heat spreader 133 of FIG. 1. In embodiments, this may facilitate the removal and dispersal of heat during operation of the computer/network dies 822a, 822b.

FIG. 8D illustrates a cross-section side view of a stage in the manufacturing process where substrate 802, which may be similar to substrate 502 of FIG. 5, may be formed. In embodiments, the substrate may include a bottom redistribution layer 802d, a bottom routing layer 802c, a core 802b, and a top routing layer 802a, which may be similar to bottom redistribution layer 102d, bottom routing layer 102c, dielectric layer 102b, and top routing layer 102a of FIG. 1.

In embodiments, cavities 804a, 804b may be formed, which may be similar to cavities 104a, 104b of FIG. 1. The cavities 804a, 804b may be formed using any technique, such as etch processes with photo resists to define the area of etching. In embodiments, there may be a special sacrificial material already embedded in the substrate 802 from the substrate manufacturing process (not shown). In these embodiments, the sacrificial material may be etched away, where a etch stop layer might be present. In other embodiments, a laser or a mechanical driller can be used to drill out the cavities 804a, 804b. In embodiments, a buildup process may be used to form the cavities 804a, 804b.

In embodiments, a TIM 830, 831, which may be similar to TIM 230, 231 of FIG. 2, may be formed on the surface of the cavities 804a, 804b. In embodiments, the TIM 830, 831 may be applied using a sputtering technique or a plating technique.

In embodiments, vias 832a, 832b, which may be similar to one or more vias 232a, 232b of FIG. 2, may be formed that thermally couple the TIM 830, 831 with a heat spreader 808, which may be similar to heat spreader 208 of FIG. 2. In embodiments, the vias 832a, 832b may be filled with thermally conductive material.

In embodiments, various other vias may be formed within the substrate 802. In embodiments, power vias 812, which may be similar to power vias 112 of FIG. 1, may be formed that may electrically couple with power in the bottom redistribution layer 802d. In embodiments, signal vias 814 may be formed that electrically couple with signals routed within the bottom redistribution layer 802d. In embodiments, solder balls 842 may be coupled with ends of the vias 812, 814 for a subsequent electrical connection shown with respect to FIG. 8E.

In addition, thermal vias 834, which may be similar to thermal vias 434 of FIG. 4, may be formed that will eventually thermally couple with the heat spreader 833 of FIG. 8C. In addition, vias 836, which may be similar to vias 436 of FIG. 4, may be placed within the substrate 802 but not directly thermally coupled with the heat spreader 833 of FIG. 8C.

FIG. 8E illustrates a cross-section side view of a stage in the manufacturing process where the structures of FIG. 8C and FIG. 8D are joined together, with the vias 834 extended so that the thermally couple heat spreader 808 with the heat spreader 833. In embodiments, a connector 803, that may be at the end of bottom redistribution layer 802d, may be used to connect the package shown in FIG. 8E with another component such as a PCB (not shown).

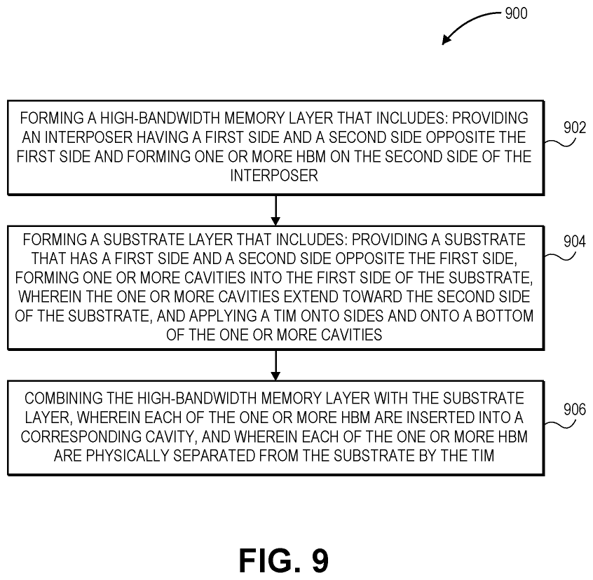

FIG. 9 illustrates an example of a process for manufacturing process for creating a package with a TIM on the surface of a die in a cavity within a substrate, in accordance with various embodiments. Process 900 may be performed using the systems, processes, and/or techniques described herein, and in particular with respect to FIGS. 1-8E.

At block 902, the process may include forming a high-bandwidth memory layer that includes: providing an interposer having a first side and a second side opposite the first side and forming one or more HBM on the second side of the interposer. In embodiments, the high-bandwidth memory layer on an interposer may be similar to FIG. 8B, that includes interposer 820 and HBM 806, 807 that are electrically coupled with the interposer 820.

At block 904, the process may further include forming a substrate layer that includes: providing a substrate that has a first side and a second side opposite the first side, forming one or more cavities into the first side of the substrate, wherein the one or more cavities extend toward the second side of the substrate, and applying a TIM onto sides and onto a bottom of the one or more cavities. In embodiments, the substrate layer may be similar to substrate 802, the cavities may be similar to cavities 804a, 804b, and the TIM may be similar to TIM 830, 831 of FIG. 8D.

At block 906, the process may further include combining the high-bandwidth memory layer with the substrate layer, wherein each of the one or more HBM are inserted into a corresponding cavity, and wherein each of the one or more HBM are physically separated from the substrate by the TIM. In embodiments, the combined high-bandwidth memory layer on the interposer with the substrate layer may be similar to FIG. 8E.

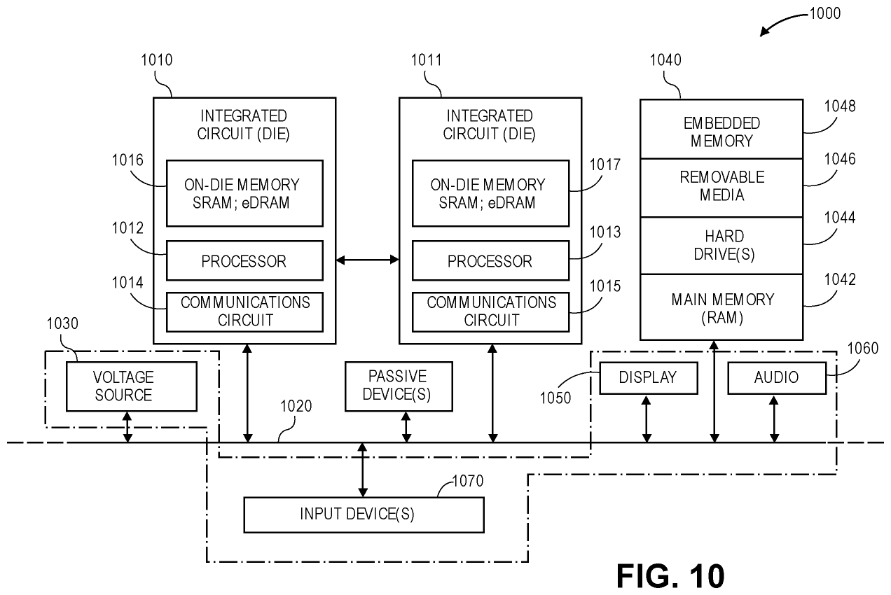

FIG. 10 is a schematic of a computer system 1000, in accordance with an embodiment. The computer system 1000 (also referred to as the electronic system 1000) as depicted can embody TIM on a surface of a die in a cavity, according to any of the several disclosed embodiments and their equivalents as set forth in this disclosure. The computer system 1000 may be a mobile device such as a netbook computer. The computer system 1000 may be a mobile device such as a wireless smart phone. The computer system 1000 may be a desktop computer. The computer system 1000 may be a hand-held reader. The computer system 1000 may be a server system. The computer system 1000 may be a supercomputer or high-performance computing system.

In an embodiment, the electronic system 1000 is a computer system that includes a system bus 1020 to electrically couple the various components of the electronic system 1000. The system bus 1020 is a single bus or any combination of busses according to various embodiments. The electronic system 1000 includes a voltage source 1030 that provides power to the integrated circuit 1010. In some embodiments, the voltage source 1030 supplies current to the integrated circuit 1010 through the system bus 1020.

The integrated circuit 1010 is electrically coupled to the system bus 1020 and includes any circuit, or combination of circuits according to an embodiment. In an embodiment, the integrated circuit 1010 includes a processor 1012 that can be of any type. As used herein, the processor 1012 may mean any type of circuit such as, but not limited to, a microprocessor, a microcontroller, a graphics processor, a digital signal processor, or another processor. In an embodiment, the processor 1012 includes, or is coupled with, TIM on a surface of a die in a cavity, as disclosed herein. In an embodiment, SRAM embodiments are found in memory caches of the processor. Other types of circuits that can be included in the integrated circuit 1010 are a custom circuit or an application-specific integrated circuit (ASIC), such as a communications circuit 1014 for use in wireless devices such as cellular telephones, smart phones, pagers, portable computers, two-way radios, and similar electronic systems, or a communications circuit for servers. In an embodiment, the integrated circuit 1010 includes on-die memory 1016 such as static random-access memory (SRAM). In an embodiment, the integrated circuit 1010 includes embedded on-die memory 1016 such as embedded dynamic random-access memory (eDRAM).

In an embodiment, the integrated circuit 1010 is complemented with a subsequent integrated circuit 1011. Useful embodiments include a dual processor 1013 and a dual communications circuit 1015 and dual on-die memory 1017 such as SRAM. In an embodiment, the dual integrated circuit 1010 includes embedded on-die memory 1017 such as eDRAM.

In an embodiment, the electronic system 1000 also includes an external memory 1040 that in turn may include one or more memory elements suitable to the particular application, such as a main memory 1042 in the form of RAM, one or more hard drives 1044, and/or one or more drives that handle removable media 1046, such as diskettes, compact disks (CDs), digital variable disks (DVDs), flash memory drives, and other removable media known in the art. The external memory 1040 may also be embedded memory 1048 such as the first die in a die stack, according to an embodiment.

In an embodiment, the electronic system 1000 also includes a display device 1050, an audio output 1060. In an embodiment, the electronic system 1000 includes an input device such as a controller 1070 that may be a keyboard, mouse, trackball, game controller, microphone, voice-recognition device, or any other input device that inputs information into the electronic system 1000. In an embodiment, an input device 1070 is a camera. In an embodiment, an input device 1070 is a digital sound recorder. In an embodiment, an input device 1070 is a camera and a digital sound recorder.

As shown herein, the integrated circuit 1010 can be implemented in a number of different embodiments, including a package substrate having TIM on a surface of a die in a cavity, according to any of the several disclosed embodiments and their equivalents, an electronic system, a computer system, one or more methods of fabricating an integrated circuit, and one or more methods of fabricating an electronic assembly that includes a package substrate having TIM on a surface of a die in a cavity, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having TIM on a surface of a die in a cavity embodiments and their equivalents. A foundation substrate may be included, as represented by the dashed line of FIG. 10. Passive devices may also be included, as is also depicted in FIG. 10.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope is to be determined entirely by the following claims, which are to be construed in accordance with established doctrines of claim interpretation.

### EXAMPLES

The following paragraphs describe examples of various embodiments.

Example 1 is an apparatus comprising: a substrate with a first side and a second side opposite the first side; a cavity within the substrate, the cavity extending from the first side of the substrate toward the second side of the substrate; and a thermal interface material (TIM) on at least a portion of a surface of the cavity.

Example 2 includes the apparatus of example 1, wherein the TIM includes a selected one or more of: copper, gold, or graphene.

Example 3 includes the apparatus of examples 1 or 2, wherein the TIM is on at least a portion of a surface at a bottom of the cavity and on at least a portion of a surface of the sides of the cavity.

Example 4 includes the apparatus of example 3, wherein the TIM completely covers the surface at the bottom of the cavity.

Example 5 includes the apparatus of examples 3 or 4, wherein the TIM completely covers the sides of the cavity.

Example 6 includes the apparatus of examples 1, 2, 3, 4, or 5, further comprising one or more vias that include thermally conductive material, the one or more vias extend from a bottom of the cavity to the second side of the substrate, wherein the one or more vias are thermally coupled with the TIM on a bottom of the cavity.

Example 7 includes the apparatus of example 6, further comprising a heat spreader on the second side of the substrate, wherein the heat spreader is thermally coupled with the one or more vias.

Example 8 is a package comprising: a substrate with a first side and a second side opposite the first side; a cavity within the substrate, the cavity extending from the first side of the substrate toward the second side of the substrate; one or more dies within the cavity; and a thermal interface material (TIM) between the one or more dies and a surface of the cavity, wherein the TIM is thermally coupled with the one or more dies.

Example 9 includes the package of example 8, wherein the one or more dies form a high-bandwidth memory (HBM).

Example 10 includes the package of examples 8 or 9, wherein the TIM includes a selected one or more of: copper, gold, carbon, or graphene.

Example 11 includes the package of examples 8, 9, or 10, wherein the TIM physically separates a bottom of the one or more dies from the substrate; and wherein the TIM physically separates sides of the one or more dies from the substrate.

Example 12 includes the package of examples 8, 9, 10, or 11, further comprising: a heat spreader on the second side of the substrate; and one or more vias that extend from the TIM to the heat spreader, wherein the one or more vias are filled with a thermally conductive material to thermally couple the TIM with the heat spreader.

Example 13 includes the package of example 12, wherein the heat spreader is a first heat spreader, wherein the one or more dies are a first set of one or more dies, and wherein the one or more vias are a first set of one or more vias; and further comprising: a second set of one or more dies on the first side of the substrate; a second heat spreader on top of the second set of one or more dies; and a second set of one or more vias thermally coupling the first heat spreader and the second heat spreader, wherein the second set of one or more vias extending through the substrate, and wherein the second set of one or more vias are filled with a thermally conductive material.

Example 14 includes the package of example 13, further comprising an interposer between the first side of the substrate and the second set of one or more dies.

Example 15 includes the package of examples 13 or 14, wherein the second set of dies include one or more compute dies or network dies, and wherein the second set of dies are electrically coupled with the first set of one or more dies.

Example 16 includes the package of examples 13, 14, or 15, further comprising a plurality of solder balls at the second side of the substrate and thermally coupled with the first heat spreader.

Example 17 includes the package of examples 8, 9, 10, 11, 12, 13, 14, 15, or 16, wherein the one or more dies are stacked on each other.

Example 18 is method comprising: forming a high-bandwidth memory layer that includes: providing an interposer having a first side and a second side opposite the first side; and forming one or more high-bandwidth memory dies (HBM) on the second side of the interposer; forming a substrate layer that includes: providing a substrate that has a first side and a second side opposite the first side; forming one or more cavities into the first side of the substrate, wherein the one or more cavities extend toward the second side of the substrate; and applying a thermal interface material (TIM) onto sides and onto a bottom of the one or more cavities; and combining the high-bandwidth memory layer with the substrate layer, wherein each of the one or more HBM are inserted into a corresponding cavity, and wherein each of the one or more HBM are physically separated from the substrate by the TIM.

Example 19 includes the method of example 18, wherein forming the substrate layer further includes: forming one or more vias extending from the second side of the substrate to the bottom of the one or more cavities, wherein the one or more vias are filled with thermally conductive material, and wherein the one or more vias thermally couple with the TIM; and forming a heat spreader on the second side of the substrate, wherein the heat spreader is thermally coupled with the thermally conductive material in the one or more vias.

Example 20 includes the method of example 19, wherein the heat spreader is a first heat spreader, and wherein forming the high-bandwidth memory layer further includes: placing one or more dies on the first side of the interposer, wherein the interposer electrically couples the one or more dies with the one or more HBM; and forming a second heat spreader on the one or more dies.

Example 21 is an apparatus comprising: a substrate with a first side and a second side opposite the first side; a cavity within the substrate, the cavity extending from the first side of the substrate toward the second side of the substrate, the cavity having a bottom surface, a first side surface, and a second side surface opposite the first side surface; and a layer on at least a portion of the bottom surface and at least one of the first side surface and second side surface of the cavity, the layer comprising a selected one or more of: copper, gold, or carbon.

Example 22 includes the apparatus of example 21, wherein the layer comprises a thermal interface material (TIM).

Example 23 includes the apparatus of examples 21 or 22, wherein the layer is sputtered.

Example 24 includes the apparatus of examples 21, 22, or 23, wherein the layer completely covers the bottom surface.

Example 25 includes the apparatus of examples 21, 22, 23, or 24, wherein the layer completely covers the first side surface or the second side surface.

Example 26 includes the apparatus of examples 21, 22, 23, 24, or 25, further comprising one or more vias that include thermally conductive material, the one or more vias extend from the bottom surface to the second side of the substrate, wherein the one or more vias are thermally coupled with the layer on the bottom surface.

Example 27 includes the apparatus of example 26, further comprising a heat spreader on the second side of the substrate, wherein the heat spreader is thermally coupled with the one or more vias.

What is claimed is:

1. An apparatus comprising:
a substrate with a first side and a second side opposite the first side;
a cavity within the substrate, the cavity extending from the first side of the substrate toward the second side of the substrate, the cavity having a bottom surface, a first side surface, and a second side surface opposite the first side surface; and
a layer on at least a portion of the bottom surface and at least one of the first side surface and second side surface of the cavity, the layer comprising a selected one or more of: copper, gold, or carbon.

2. The apparatus of claim 1, wherein the layer comprises a thermal interface material (TIM).

3. The apparatus of claim 1, wherein the layer is sputtered.

4. The apparatus of claim 1, wherein the layer completely covers the bottom surface.

5. The apparatus of claim 1, wherein the layer completely covers the first side surface or the second side surface.

6. The apparatus of claim 1, further comprising one or more vias that include thermally conductive material, the one or more vias extend from the bottom surface to the second side of the substrate, wherein the one or more vias are thermally coupled with the layer on the bottom surface.

7. The apparatus of claim 6, further comprising a heat spreader on the second side of the substrate, wherein the heat spreader is thermally coupled with the one or more vias.

8. A package comprising:
a substrate with a first side and a second side opposite the first side;
a cavity within the substrate, the cavity extending from the first side of the substrate toward the second side of the substrate;
one or more dies within the cavity; and
a thermal interface material (TIM) between the one or more dies and a surface of the cavity, wherein the TIM is thermally coupled with the one or more dies.

9. The package of claim 8, wherein the one or more dies form a high-bandwidth memory (HBM).

10. The package of claim 8, wherein the TIM includes a selected one or more of: copper, gold, or graphene.

11. The package of claim 8, wherein the TIM physically separates a bottom of the one or more dies from the substrate; and wherein the TIM physically separates sides of the one or more dies from the substrate.

12. The package of claim 8, further comprising:
a heat spreader on the second side of the substrate; and
one or more vias that extend from the TIM to the heat spreader, wherein the one or more vias are filled with a thermally conductive material to thermally couple the TIM with the heat spreader.

13. The package of claim 12, wherein the heat spreader is a first heat spreader, wherein the one or more dies are a first set of one or more dies, and wherein the one or more vias are a first set of one or more vias; and further comprising:
a second set of one or more dies on the first side of the substrate;
a second heat spreader on top of the second set of one or more dies; and
a second set of one or more vias thermally coupling the first heat spreader and the second heat spreader, wherein the second set of one or more vias extending through the substrate, and wherein the second set of one or more vias are filled with a thermally conductive material.

14. The package of claim 13, further comprising an interposer between the first side of the substrate and the second set of one or more dies.

15. The package of claim 13, wherein the second set of one or more dies include one or more compute dies or network dies, and wherein the second set of one or more dies are electrically coupled with the first set of one or more dies.

16. The package of claim 13, further comprising a plurality of solder balls at the second side of the substrate and thermally coupled with the first heat spreader.

17. The package of claim 8, wherein the one or more dies are stacked on each other.

18. A method comprising:
forming a high-bandwidth memory layer that includes:
providing an interposer having a first side and a second side opposite the first side; and
forming one or more high-bandwidth memory dies (HBM) on the second side of the interposer;
forming a substrate layer that includes:
providing a substrate that has a first side and a second side opposite the first side;
forming one or more cavities into the first side of the substrate, wherein the one or more cavities extend toward the second side of the substrate; and
applying a thermal interface material (TIM) onto sides and onto a bottom of the one or more cavities; and
combining the high-bandwidth memory layer with the substrate layer, wherein each of the one or more HBM are inserted into a corresponding cavity, and wherein each of the one or more HBM are physically separated from the substrate by the TIM.

19. The method of claim 18, wherein forming the substrate layer further includes:
forming one or more vias extending from the second side of the substrate to the bottom of the one or more cavities, wherein the one or more vias are filled with thermally conductive material, and wherein the one or more vias thermally couple with the TIM; and
forming a heat spreader on the second side of the substrate, wherein the heat spreader is thermally coupled with the thermally conductive material in the one or more vias.

20. The method of claim 19, wherein the heat spreader is a first heat spreader, and wherein forming the high-bandwidth memory layer further includes:
placing one or more dies on the first side of the interposer, wherein the interposer electrically couples the one or more dies with the one or more HBM; and
forming a second heat spreader on the one or more dies.
